(19) United States
(12) Patent Application Publication
(10) Pub. No.: US 2023/0354606 A1
(43) Pub. Date: Nov. 2, 2023

(54) SEMICONDUCTOR DEVICE

(71) Applicant: Kioxia Corporation, Tokyo (JP)

(72) Inventors: Hideo WADA, Yokkaichi (JP); Hironobu HAMANAKA, Yokkaichi (JP)

(73) Assignee: Kioxia Corporation, Tokyo (JP)

(21) Appl. No.: 18/186,237

(22) Filed: Mar. 20, 2023

(30) Foreign Application Priority Data
Apr. 28, 2022 (JP) 2022-074771
Dec. 21, 2022 (JP) 2022-204771

(51) Int. Cl. H10B 43/27; H10B 80/00

(52) U.S. Cl. CPC H10B 43/27; H10B 80/00

(57) ABSTRACT

A device includes a cell-array above transistors. A first semiconductor layer is above the cell-array and has a first surface on a side on which the cell-array is provided and a second surface opposite to the first surface. A first metal-wire is above the second surface and electrically connected to the first semiconductor layer. A second metal-wire is above the second surface to be present in the same layer as the first metal-wire and is not in contact with the first metal-wire and the first semiconductor layer. A first contact is below the first metal-wire, extends in a first direction from the first surface to the second surface, and electrically connects one of the transistors to the first metal-wire. A second contact is below the second metal-wire, extends in the first direction, and electrically connects another one of the transistors to the second metal-wire.

### CROSS REFERENCE TO RELATED APPLICATIONS

This application is based upon and claims the benefit of priority from the prior Japanese Patent Applications No. 2022-074771, filed on Apr. 28, 2022 and No. 2022-204771, filed on Dec. 21, 2022, the entire contents of which are incorporated herein by reference.

### FIELD

The embodiments of the present invention relate to a semiconductor device.

### BACKGROUND

There is known a semiconductor device with a memory cell array provided above a CMOS (Complementary Metal Oxide Semiconductor) circuit. For such a semiconductor device, a configuration has been proposed in which a semiconductor source layer is provided on the memory cell array, and metal source lines are provided on the semiconductor source layer. The metal source lines reduce electrical resistance of the entire source layer by being connected to the semiconductor source layer. However, a metal layer forming the metal source lines is used only as source lines, but is not used for other purposes.

### BRIEF DESCRIPTION OF THE DRAWINGS

FIG. 1 is a cross-sectional view illustrating a configuration example of a semiconductor device according to a first embodiment;

FIG. 2 is a plan view of a stack according to the first embodiment;

FIG. 3 is a schematic cross-sectional view of an example of a memory cell having a three-dimensional configuration according to the first embodiment;

FIG. 4 is a schematic cross-sectional view of an example of the memory cell having a three-dimensional configuration according to the first embodiment;

FIG. 5 is a schematic cross-sectional view illustrating a metal wiring layer according to the first embodiment;

FIG. 6A is a schematic cross-sectional view along a line A-A in FIG. 5;

FIG. 6B is a schematic cross-sectional view illustrating a comparative example of FIG. 6A;

FIG. 6C is a schematic cross-sectional view along a line B-B in FIG. 5;

FIG. 6D is a schematic cross-sectional view along a line C-C in FIG. 5;

FIG. 7 is a schematic plan view illustrating the metal wiring layer according to the first embodiment;

FIG. 8 includes graphs indicating change of a resistance of a source layer according to the first embodiment;

FIG. 9 is a schematic plan view illustrating a metal wiring layer according to a second embodiment;

FIG. 10 includes graphs indicating change of a resistance of a source layer according to the second embodiment;

FIG. 11 is a schematic plan view illustrating a metal wiring layer according to a third embodiment;

FIG. 12 includes graphs indicating change of a resistance of a source layer according to the third embodiment;

FIG. 13 is a block diagram illustrating a configuration example of a semiconductor device to which any of the above embodiments is applied;

FIG. 14 is a circuit diagram illustrating an example of a circuit configuration of a memory cell array;

FIG. 15 is a cross-sectional view illustrating another configuration example of the semiconductor storage device;

FIG. 16 is a plan view illustrating a configuration example of a semiconductor device according to a fourth embodiment;

FIG. 17 is a cross-sectional view illustrating a configuration example of the semiconductor device according to the fourth embodiment;

FIG. 18 is a cross-sectional view illustrating a configuration example of the semiconductor device according to the fourth embodiment; and

FIG. 19 is a perspective view illustrating a configuration example of the semiconductor device according to the fourth embodiment.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A semiconductor device according to the present embodiment includes transistors. A memory cell array is provided above the transistors. A first semiconductor layer is provided above the memory cell array and has a first surface on a side on which the memory cell array is provided and a second surface opposite to the first surface. A first metal wire is provided above the second surface and electrically connected to the first semiconductor layer. A second metal wire is provided above the second surface to be present in the same layer as the first metal wire and is not in contact with the first metal wire and the first semiconductor layer. A first contact is provided below the first metal wire, extends in a first direction from the first surface to the second surface, and electrically connects one of the transistors to the first metal wire. A second contact is provided below the second metal wire, extends in the first direction, and electrically connects another one of the transistors to the second metal wire.

### First Embodiment

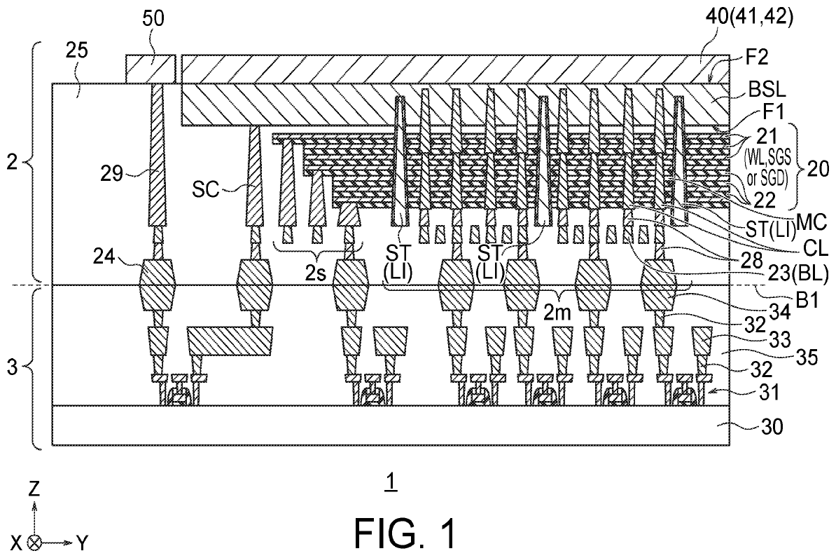

FIG. 1 is a cross-sectional view illustrating a configuration example of a semiconductor device 1 according to a first embodiment. In the following description, a stacking direction of a stack 20 is defined as a Z-direction. One direction that crosses the Z-direction, for example, at right angles is defined as a Y-direction. One direction that crosses the Z-direction and the Y-direction, for example, at right angles is defined as an X-direction. In the present specification, the X-direction is an example of a third direction, the Y-direction is an example of a second direction, and the Z-direction is an example of a first direction.

The semiconductor device 1 includes an array chip 2 having a memory cell array and a CMOS chip 3 having a CMOS circuit. The array chip 2 and the CMOS chip 3 are bonded together at a bonding surface B1 at which they are electrically connected to each other via joined wires. FIG. 1 illustrates a state where the array chip 2 is placed on the CMOS chip 3.

The CMOS chip 3 includes a substrate 30, transistors 31, vias 32, wires 33 and 34, and an interlayer dielectric film 35.

The substrate 30 is a semiconductor substrate, for example, a silicon substrate. The transistors 31 are NMOS or PMOS transistors provided on the substrate 30. The transistor 31 constitutes a CMOS circuit controlling the memory cell array of the array chip 2, for example. The transistors 31 are an example of a plurality of logic circuits. A semiconductor element other than the transistors 31, such as a resistor element and a capacitor element, may be formed on the substrate 30.

The via 32 electrically connects the transistor 31 and the wire 33 to each other or the wire 33 and the wire 34 to each other. The wires 33 and 34 constitute a multilayer wiring structure in the interlayer dielectric film 35. The wire 34 is embedded in the interlayer dielectric film 35 and is exposed in a surface of the interlayer dielectric film 35 to be flush therewith. The wires 33 and 34 are electrically connected to the transistors 31 and the like. A low-resistance metal, such as copper and tungsten, is used for the vias 32 and the wires 33 and 34. The interlayer dielectric film 35 covers and protects the transistors 31, the vias 32, and the wires 33 and 34. An insulating film, such as a silicon oxide film, is used as the interlayer dielectric film 35.

The array chip 2 includes the stack 20, column portions CL, slits ST (LI), a semiconductor source layer BSL, a metal layer 40, a contact 29, and a bonding pad 50.

The stack 20 is provided above the transistors 31 and located in the Z-direction with respect to the substrate 30. The stack 20 is configured by a plurality of electrode films 21 and a plurality of insulating films 22 alternately stacked along the Z-direction. The stack 20 constitutes the memory cell array. A conductive metal, for example, tungsten is used for the electrode films 21. An insulating film, for example, a silicon oxide film is used as the insulating films 22. The insulating films 22 insulate the electrode films 21 from each other. That is, the electrode films 21 are stacked while being insulated from each other. The number of the stacked electrode films 21 and the number of the stacked insulating films 22 may be any number. The insulating films 22 may be porous insulating films or air gaps, for example.

The electrode films 21 at upper and lower ends in the Z-direction of the stack 20 serve as a source-side selection gate SGS and a drain-side selection gate SGD, the number of the electrode films 21 at each of the ends of the stack being one or more. The electrode films 21 between the source-side selection gate SGS and the drain-side selection gate SGD serve as word lines WL. The word lines WL serve as gate electrodes of memory cells MC. The drain-side selection gate SGD is a gate electrode of a drain-side selection transistor. The source-side selection gate SGS is provided in an upper region of the stack 20. The drain-side selection gate SGD is provided in a lower region of the stack 20. The lower region means a region of the stack 20 closer to the CMOS chip 3, and the upper region means a region of stack 20 farther from the CMOS chip 3 (closer to the metal layer 40).

The semiconductor device 1 includes the memory cells MC connected in series between a source-side selection transistor and the drain-side selection transistor. The configuration in which the source-side selection transistor, the memory cells MC, and the drain-side selection transistor are connected in series is called a “memory string” or a “NAND string”. The memory string is connected to a bit line BL, for example, via a via 28. The bit line BL is a wire 23 provided below the stack 20 and extending in the X-direction (the direction perpendicular to the drawing of FIG. 1).

The column portions CL are provided in the stack 20. The column portions CL extend in the stack 20 to penetrate through the stack 20 in the stacking direction (the Z-direction) from the via 28 connected to the bit line BL to the semiconductor source layer BSL. The internal structure of each column portion CL will be described later. The column portions CL are formed in two stages in the Z-direction in the present embodiment, because the column portions CL have a high aspect ratio. However, the column portions CL can be formed in one stage.

Further, the slits ST (LI) are provided in the stack 20. The slits ST (LI) extend in the X-direction and penetrate through the stack 20 in the stacking direction (the Z-direction) of the stack 20. The slits ST (LI) are filled with an insulating film, such as a silicon oxide film, and the insulating film is formed in a plate shape. The slits ST (LI) electrically isolate the electrode films 21 of the stack 20. Alternatively, the inner wall of each slit ST (LI) may be covered with an insulating film, such as a silicon oxide film, and a conductive material may be embedded inside the insulating film. In this case, the conductive material also serves as a source wire LI reaching the semiconductor source layer BSL. That is, the slits ST may be the source wires LI electrically isolated from the electrode films 21 of the stack that constitutes the memory cell array and electrically connected to the semiconductor source layer BSL. The slits may also be referred to as ST (LI).

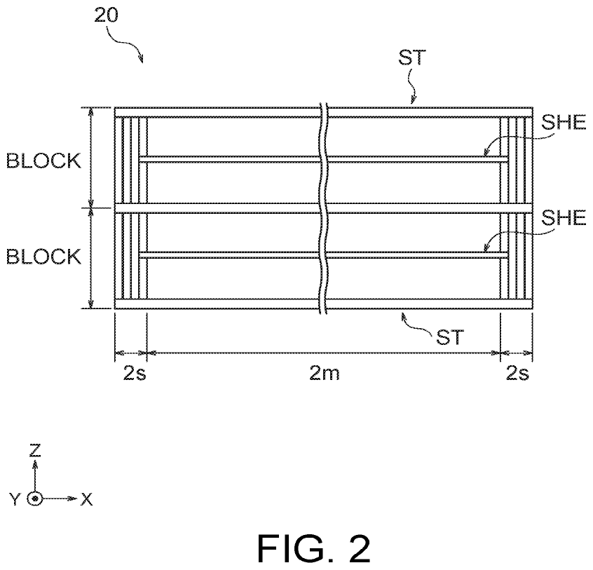

The semiconductor source layer BSL is provided on the stack 20. The semiconductor source layer BSL is an example of a first semiconductor layer. The semiconductor source layer BSL is provided to correspond to the stack 20. The semiconductor source layer BSL has a first surface F1 and a second surface F2 opposite to the first surface F1. The stack 20 (the memory cell array) is provided on the first surface F1 side of the semiconductor source layer BSL, and the metal layer 40 is provided on the second surface F2 side. The metal layer 40 includes source lines 41 and power lines 42. The source lines 41 and the power lines 42 will be described in detail later. The semiconductor source layer BSL is connected to one ends of the column portions CL in common to supply a common source potential to the column portions CL belonging to the same memory cell array 2m. That is, the semiconductor source layer BSL serves as a common source electrode of the memory cell array 2m. A conductive material, such as doped polysilicon, is used for the semiconductor source layer BSL. A metal material that is lower in resistance than the semiconductor source layer BSL, for example, copper, aluminum, or tungsten is used for the metal layer 40. Reference sign 2s denotes a stair portion of the electrode films 21 provided for connecting a contact to each of the electrode films 21. The stair portion 2s will be described later with reference to FIG. 2.

Meanwhile, the bonding pad 50 is provided above the stack 20 in a region where the semiconductor source layer BSL is not provided. The bonding pad 50 is an example of a first electrode. The bonding pad 50 is connected to a metal wire (not illustrated) or the like and receives power supply from outside of the semiconductor device 1. The bonding pad 50 is connected to the transistor 31 of the CMOS chip 3 via the contact 29 and a wire 24 and the wire 34. With this configuration, external power supplied from the bonding pad 50 is supplied to the transistor 31. A low-resistance metal, such as copper and tungsten, is used for the contact 29.

In the present embodiment, the array chip 2 and the CMOS chip 3 are formed separately from each other and bonded together at the bonding surface B1. Therefore, the transistors 31 are not provided in the array chip 2. Further, the stack 20 (the memory cell array) is not provided in the CMOS chip 3. The transistors 31 and the stack 20 are both arranged on the first surface F1 side of the semiconductor source layer BSL. The transistors 31 are arranged on the opposite side to the second surface F2 side on which the metal layer 40 is arranged.

The vias 28 and the wires 23 and 24 are provided below the stack 20. The wires 23 and 24 are embedded in an interlayer dielectric film 25 and are exposed in a surface of the interlayer dielectric film 25 to be substantially flush therewith. The wires 23 and 24 are electrically connected to, for example, a semiconductor body 210 of the column portion CL. A low-resistance metal, such as copper and tungsten, is used for the vias 28 and the wires 23 and 24. The interlayer dielectric film 25 covers and protects the stack 20, the vias 28, and the wires 23 and 24. An insulating film, such as a silicon oxide film, is used as the interlayer dielectric film 25.

The interlayer dielectric film 25 and the interlayer dielectric film 35 are bonded together at the bonding surface B1, and the wires 24 and 34 are also bonded together at the bonding surface B1 to be substantially flush therewith. Accordingly, the array chip 2 and the CMOS chip 3 are electrically connected to each other via the wires 24 and 34.

FIG. 2 is a schematic plan view of the stack 20. The stack 20 includes the stair portion 2s and the memory cell array 2m. The stair portion 2s is provided at an edge of the stack 20. The memory cell array 2m is sandwiched between the stair portions 2s or surrounded by the stair portion 2s. The slits ST (LI) are provided from the stair portion 2s at one end of the stack 20 to the stair portion 2s at the other end of the stack 20 through the memory cell array 2m. Slits SHE are provided at least in the memory cell array 2m. The slits SHE are shallower than the slits ST (LI) and extend substantially parallel to the slits ST (LI). The slits SHE are provided for electrically isolating the electrode films 21 for each drain-side selection gate SGD.

A portion of the stack 20 sandwiched between two of the slits ST (LI) illustrated in FIG. 2 is called a block (BLOCK). The block is, for example, the minimum unit for erasing data. The slits SHE are provided in the block. The stack 20 between the slit ST (LI) and the slit SHE is called a finger. The drain-side selection gate SGD is divided for each finger. Accordingly, it is possible to place one finger in a block in a selected state by the drain-side selection gate SGD in data writing and data reading.

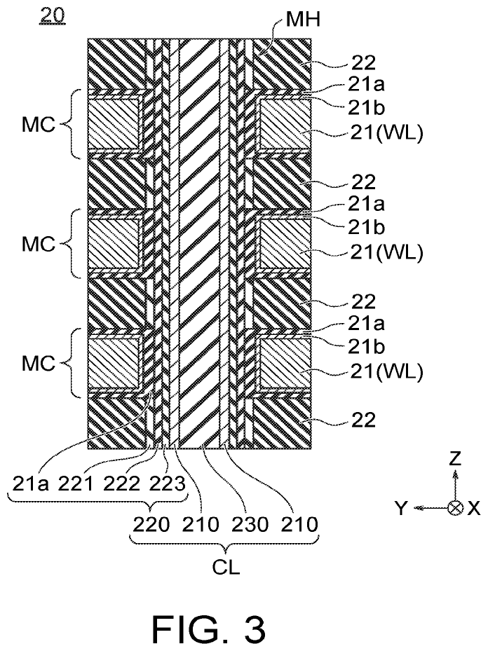

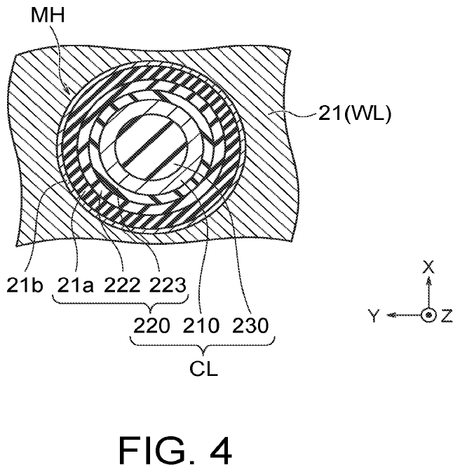

FIGS. 3 and 4 are schematic cross-sectional views of an example of a memory cell having a three-dimensional configuration. Each of the column portions CL is provided in a memory hole MH provided in the stack 20. Each column portion CL penetrates through the stack 20 from an upper end of the stack 20 along the Z-direction and is provided in the stack and in the semiconductor source layer BSL. The column portions CL each include the semiconductor body 210, a memory film 220, and a core layer 230. The column portion CL includes the core layer 230 provided at its center, the semiconductor body (a semiconductor member) 210 provided around the core layer 230, and the memory film (a charge storage member) 220 provided around the semiconductor body 210. The semiconductor body 210 extends in the stack 20 in the stacking direction (the Z direction). The semiconductor body 210 is electrically connected to the semiconductor source layer BSL. The memory film 220 is provided between the semiconductor body 210 and the electrode film 21 and has a charge trapping portion. The column portions CL selected one by one from the respective fingers are connected to one bit line BL in common via the vias 28 in FIG. 1. The column portions CL are provided in a region of the memory cell array 2m, for example.

As illustrated in FIG. 4, the shape of the memory hole MH in the X-Y plane is, for example, circular or elliptical. A block insulating film 21a that constitutes a portion of the memory film 220 may be provided between the electrode film 21 and the insulating film 22. The block insulating film 21a is, for example, a silicon oxide film or a metal oxide film. One example of the metal oxide is aluminum oxide. A barrier film 21b may be provided between the electrode film 21 and the insulating film 22 and between the electrode film 21 and the memory film 220. In a case where the electrode film 21 is made of tungsten, for example, a multilayer film of titanium nitride and titanium, for example, is selected as the barrier film 21b. The block insulating film 21a prevents back tunneling of electric charges from the electrode film 21 to the memory film 220. The barrier film 21b improves adhesion between the electrode film 21 and the block insulating film 21a.

The shape of the semiconductor body 210 as a semiconductor member is a tube with a bottom, for example. The semiconductor body 210 is made of, for example, polysilicon. The semiconductor body 210 is made of, for example, undoped silicon. The semiconductor body 210 may be made of p-type silicon. The semiconductor body 210 serves as a channel of each of the drain-side selection transistor STD, the memory cell MC, and a source-side selection transistor STS. One ends of the semiconductor bodies 210 in the same memory cell array 2m are electrically connected to the semiconductor source layer BSL in common.

A portion of the memory film 220 other than the block insulating film 21a is provided between the inner wall of the memory hole MH and the semiconductor body 210. The shape of the memory film 220 is tubular, for example. The memory cells MC each have a storage region between the semiconductor body 210 and the electrode film 21 serving as the word line WL, and are stacked in the Z-direction. The memory film 220 includes a cover insulating film 221, a charge trapping film 222, and a tunnel insulating film 223, for example. The semiconductor body 210, the charge trapping film 222, and the tunnel insulating film 223 extend in the Z-axis direction.

The cover insulating film 221 is provided between the insulating film 22 and the charge trapping film 222. The cover insulating film 221 contains silicon oxide, for example. The cover insulating film 221 protects the charge trapping film 222 from being etched in replacement of sacrifice films (not illustrated) with the electrode films 21 (in a replacement process). The cover insulating film 221 may be removed from between the electrode film 21 and the memory film 220 in the replacement process. In this case, the block insulating film 21a, for example, is not provided between the electrode film 21 and the charge trapping film 222 as illustrated in FIGS. 3 and 4. Further, it is allowable that the cover insulating film 221 is not included in a case where the replacement process is not used for forming the electrode films 21.

The charge trapping film 222 is provided between the block insulating film 21a and the cover insulating film 221, and the tunnel insulating film 223. The charge trapping film 222 contains silicon nitride, for example, and has trap sites that trap therein electric charges. A portion of the charge trapping film 222, sandwiched between the electrode film 21 serving as the word line WL and the semiconductor body 210, constitutes the storage region of the memory cell MC as a charge trapping portion. A threshold voltage of the memory cell MC is changed depending on whether electric charges are present in the charge trapping portion or in accordance with the amount of electric charges trapped in the charge trapping portion. The memory cell MC thus retains information.

The tunnel insulating film 223 is provided between the semiconductor body 210 and the charge trapping film 222. The tunnel insulating film 223 contains, for example, silicon oxide, or silicon oxide and silicon nitride. The tunnel insulating film 223 is a potential barrier between the semiconductor body 210 and the charge trapping film 222. For example, when electrons are injected from the semiconductor body 210 to the charge trapping portion (a write operation) and when holes are injected from the semiconductor body 210 to the charge trapping portion (an erase operation), each of the electrons and the holes pass (tunnel) through the potential barrier by the tunnel insulating film 223.

The core layer 230 is embedded in a space within the tubular semiconductor body 210. The shape of the core layer 230 is columnar, for example. The core layer 230 contains, for example, silicon oxide and is insulating.

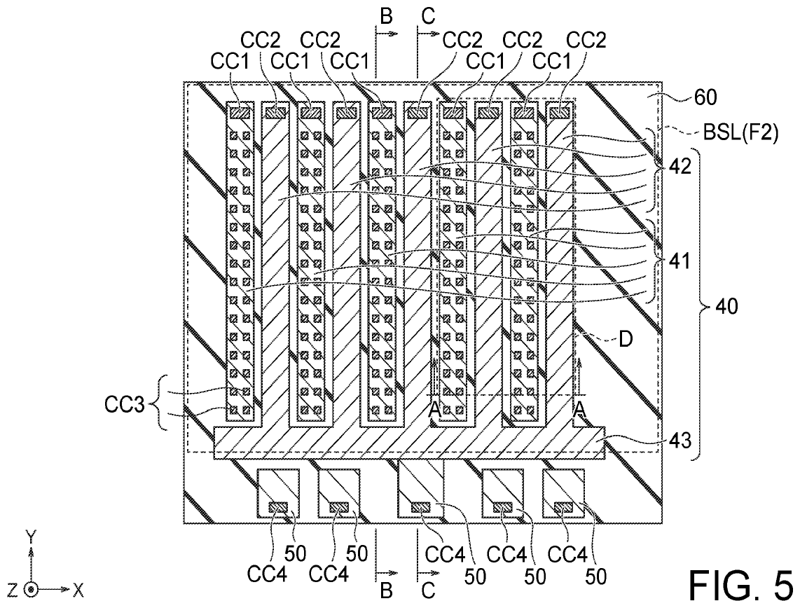

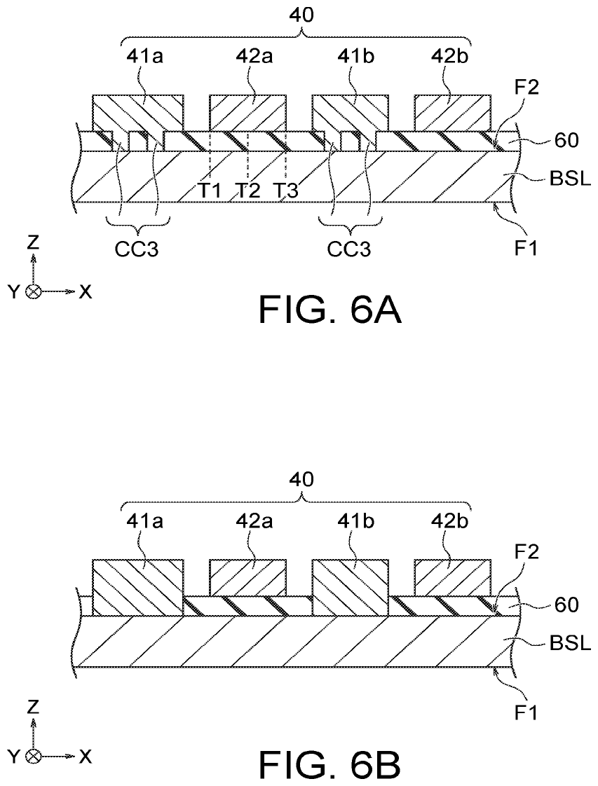

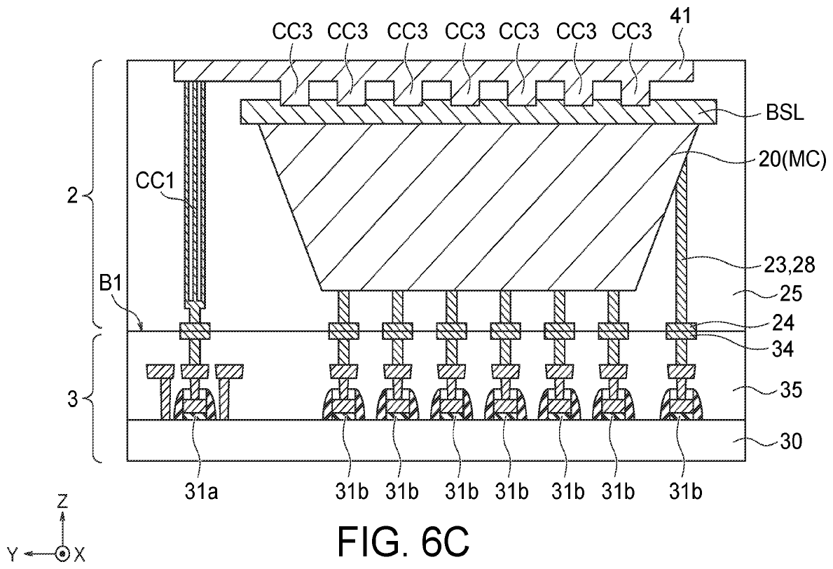

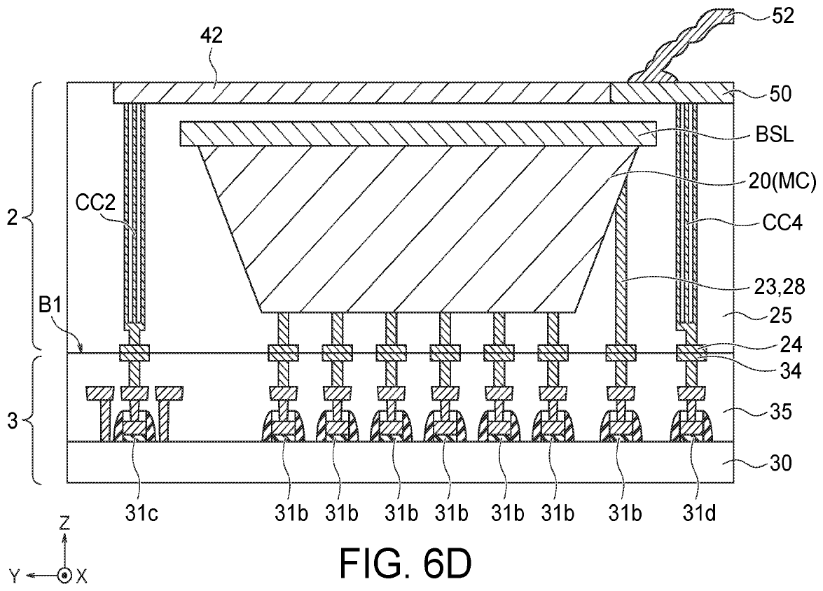

Next, the semiconductor source layer BSL, an insulation layer 60, and the metal layer 40 (the source lines 41, the power lines 42, and a power line 43) are described with reference to FIGS. 5 to 6B.

FIG. 5 illustrates a configuration of the metal layer 40 when the semiconductor device 1 is viewed from the Z-axis direction. FIGS. 6A and 6B are schematic cross-sectional views along a line A-A in FIG. 5. In the following description, source lines 41a and 41b are also referred to as the source lines 41 collectively, and power lines 42a and 42b are also referred to as the power lines 42 collectively. In addition, the source lines 41, the power lines 42, and the power line 43 are also referred to as the metal layer 40 collectively.

The semiconductor source layer BSL is provided above the memory cell MC as illustrated in FIG. 1. As illustrated in FIGS. 6A and 6B, the semiconductor source layer BSL has the first surface F1 on a side on which the memory cell MC is arranged and the second surface F2 opposite to the first surface F1. The semiconductor source layer BSL is an example of a first semiconductor layer and contains doped polysilicon. The semiconductor source layer BSL is electrically connected to the memory cell MC and supplies a cell source voltage for causing the memory cell MC to operate.

The insulation layer 60 is provided on the second surface F2 of the semiconductor source layer BSL. The insulation layer 60 is an example of a first insulation layer. Silicon oxide is used for the insulation layer 60, for example. As will be described later, the insulation layer 60 electrically isolates the power lines 42 and the semiconductor source layer BSL from each other, but allows the source lines 41 and the semiconductor source layer BSL to be electrically connected to each other via contact holes provided in the insulation layer 60.

The metal layer 40 is provided on the second surface F2 of the semiconductor source layer BSL. In the present embodiment, the above-described insulation layer 60 is provided between the metal layer 40 and the semiconductor source layer BSL. As illustrated in FIG. 5, the metal layer 40 includes the source lines 41 and the power lines 42 and 43. A metal with a lower resistance than the semiconductor source layer BSL is used for the source lines 41 and the power lines 42 and 43. Examples of such a metal is aluminum. Although five of the source lines 41 and five of the power lines 42 are illustrated in FIG. 5, the number of the source lines 41 and the number of the power lines 42 are any number.

Here, the source lines 41 and the power lines 42 and 43 are described in detail.

The source lines 41 are provided on the second surface F2 side of the semiconductor source layer BSL and are electrically connected to the semiconductor source layer BSL. The source lines 41 are an example of a first metal wiring layer. As illustrated in FIG. 6A, the source lines 41 may be connected to the semiconductor source layer BSL via contacts CC3. Alternatively, as illustrated in FIG. 6B, the source lines 41 may be connected to the semiconductor source layer BSL at their entire bottom surface.

FIGS. 6A and 6B are schematic cross-sectional views illustrating examples of a connection structure between the source line 41 and the semiconductor source layer BSL. In FIG. 6A, a low-resistance metal (e.g., aluminum) is filled in a contact hole selectively formed in the insulation layer 60, whereby the contact CC3 is formed. Meanwhile, in FIG. 6B, the insulation layer 60 under the source lines 41 is entirely removed, whereby the entire bottom surface of each source line 41 is in contact with the semiconductor source layer BSL. Therefore, the source line 41 in FIG. 6B is wider in area of contact with the semiconductor source layer BSL than the source line 41 in FIG. 6A. Consequently, the resistance of contact between the source line 41 in FIG. 6B and the semiconductor source layer BSL is lower than that between the source line 41 in FIG. 6A and the semiconductor source layer BSL. Considering the entire resistance of a source layer 41, BSL, the configuration in FIG. 6B is preferable. However, the configuration in FIG. 6A can be employed as long as the entire resistance of the source layer 41, BSL is sufficiently low when connection is established via the contact CC3.

As described above, the source lines 41 and the semiconductor source layer BSL are electrically connected to each other and constitute a source layer integrally. Consequently, the source lines 41 and the semiconductor source layer BSL are also referred to as the source layer 41, BSL collectively. Since the source lines 41 are made of a metal that is lower in resistance than the semiconductor source layer BSL as described above, the source layer 41, BSL as a whole has a lower resistance than the semiconductor source layer BSL. That is, the source lines 41 have an effect of lowering the resistance of the source layer 41, BSL. By lowering the resistance of the source layer 41, BSL, voltage drop of the cell source voltage in the source layer 41, BSL can be prevented, thereby resulting in reduction of power consumption. The source line 41 is connected to the contact CC1 and, via the contact CC1, is electrically connected to any of the transistors 31 of the CMOS chip 3. With this configuration, the source line 41 applies the cell source voltage to the memory cell MC via the semiconductor source layer BSL. The cell source voltage is a voltage applied to the source layer 41, BSL via the contact CC1 and serves as a source voltage of the memory cell MC.

The power lines 42 are provided on the second surface F2 side of the semiconductor source layer BSL and are electrically isolated from the source layer 41, BSL. The power lines 42 are an example of a second metal wiring layer. As illustrated in FIG. 5, five of the power lines 42 are connected to the power line 43 in common, and the power line 43 is connected to the bonding pad 50. The bonding pad 50 is an example of a first electrode. The power line 42 is provided with a contact CC2, and the bonding pad 50 is provided with a contact CC4. The contacts CC2 and CC4 are each connected to any of the transistors 31 of the CMOS chip 3.

In the present embodiment, the power line 42 is provided between the source lines 41, and they are present in the same layer on the semiconductor source layer BSL (the insulation layer 60). More specifically, in plan view from the Z-direction, the source lines 41 and the power lines 42 extend in the Y-direction, are electrically isolated from each other, and are alternately arranged (in stripes) in the X-direction. The source lines 41 and the power lines 42 have a rectangular shape with its longitudinal direction along the Y-direction. By providing both the source lines 41 and the power lines 42 in the same layer as in the present embodiment, the source lines 41 and the power lines 42 can be formed by a single layer without using a multilayer structure.

It is preferable that the source lines 42 and the power lines 42 are alternately arranged substantially evenly. For example, the source line 41a, the power line 42a, the source line 41b, and the power line 42b may be arranged in the X-direction in this order at substantially regular intervals. In this case, the above arrangement is made in such a manner that, in the X-direction, the distance between the source line 41a and the source line 41b and the distance between the power line 42a and the power line 42b are substantially the same as each other. By alternately arranging the source lines 41 and the power lines 42 at substantially regular intervals as described above, the source lines 41 or the power lines 42 can be prevented from being unevenly arranged on a part of the second surface F2 of the semiconductor source layer BSL, for example. Accordingly, while the source lines 41 and the power lines 42 are present in the same layer, the resistance of the source layer 41, BSL as a whole can be lowered. The width in the X-direction of the source line 41 and the width of the power line 42 may be equal to each other or different from each other.

FIG. 6C is a schematic cross-sectional view illustrating a cross-section along a line B-B in FIG. 5 (a cross-section of the source line 41 portion). The configuration related to the source line 41 is described with reference to FIG. 6C.

The source line 41 is provided with the contact CC1 and the contact CC3. The contact CC1 is an example of a first contact, and the contact CC3 is an example of a third contact. The contact CC1 extends in the Z-direction in the interlayer dielectric film 25 and is electrically connected to a transistor 31a via the via 28, the wire 24, and the wire 34. The transistor 31a is an example of a first logic circuit. It suffices that the transistor 31a is a circuit serving as a cell source driver circuit. That is, the transistor 31a applies a source voltage to the source layer 41, BSL via the via 28, the wires 24 and 34, and the contact CC1 and further to the memory cell MC via the source layer 41, BSL.

A transistor 31b is electrically connected to the column portion CL (see FIG. 1) in the memory cell MC and applies a drain voltage to the column portion CL. A cell current is thus caused to flow to the memory cell MC by application of the source voltage and the drain voltage to the memory cell MC by the transistors 31a and 31b. Accordingly, data can be written to or read from the memory cell MC.

FIG. 6D schematically illustrates a cross-section along a line C-C in FIG. 5 (a cross-section of the power line 42 portion). The configuration related to the power line 42 is described with reference to FIG. 6D.

The power line 42 is provided with the contact CC2, and the bonding pad 50 is provided with the contact CC4. The contact CC2 is an example of a second contact, and the contact CC4 is an example of a fourth contact. The contact CC2 extends in the Z-direction in the interlayer dielectric film 25 and is electrically connected to a transistor 31c via the via 28, the wire 24, and the wire 34. The transistor 31c is an example of a second logic circuit. Similarly, the contact CC4 is connected to a transistor 31d. The transistor 31d is an example of a third logic circuit. A bonding wire 52 is connected to the bonding pad 50, and is further connected to an external power supply (not illustrated). Accordingly, power for causing the semiconductor device 1 (the array chip 2 and the CMOS chip 3) to operate is supplied from the external power supply via the bonding pad 50. That is, the external power from the bonding wire 52 is supplied to the transistor 31c via the power line 42 and the contact CC2, and to the transistor 31d via the contact CC4.

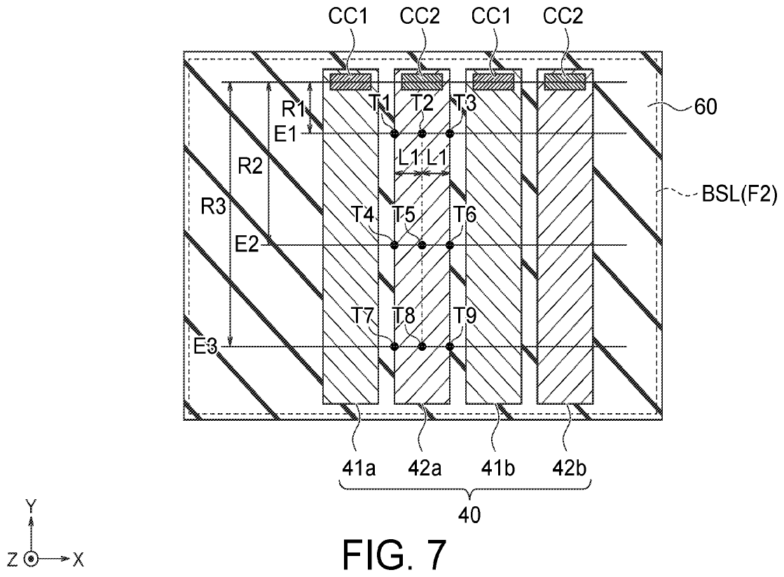

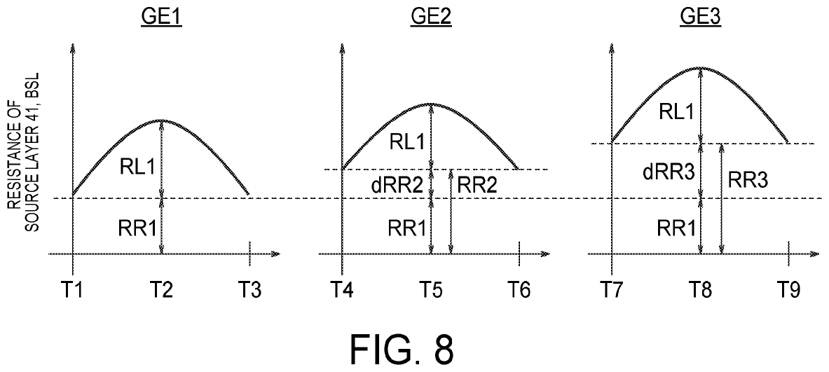

Next, a resistance at each of positions (points T1 to T9) in the source layer 41, BSL is described in detail with reference to FIGS. 7 and 8.

FIG. 7 is a schematic plan view illustrating the source lines 41, the power lines 42, and the contacts CC1. FIG. 7 corresponds to a region D in FIG. 5.

FIG. 7 illustrates line segments E1 to E3 extending in the X-direction from the side close to the contact CC1. The line segments E1 to E3 are virtual lines. Distances from the contact CC1 to the line segments E1 to E3 are denoted by R1 to R3, respectively.

Further, it is assumed that, among points on the line segment E1 in the power line 42a, the closest point to the source line 41a is the point T1, the closest point to the source line 41b is the point T3, and an intermediate point between the point T1 and the point T3 is the point T2. That is, the point T2 is farther from the source line 41a than the point T1 and farther from the source line 41b than the point T3. In this case, the point T2 is farther from the source line (41a or 41b) than the point T1 or T3 on the line segment E1 in the power line 42a. Therefore, as for the points T1 to T3, the resistance of the source layer 41, BSL from the contact CC1 is the highest at the point T2.

Similarly, it is assumed that, among points on the line segment E2 in the power line 42a, the closest point to the source line 41a is the point T4, the closest point to the source line 41b is the point T6, and an intermediate point between the point T4 and the point T6 is the point T5. That is, the point T5 is farther from the source line 41a than the point T4 and farther from the source line 41b than the point T6. In this case, the point T5 is farther from the source line (41a or 41b) than the point T4 or T6 on the line segment E2 in the power line 42a. Therefore, as for the points T4 to T6, the resistance of the source layer 41, BSL from the contact CC1 is the highest at the point T5.

Furthermore, it is assumed that, among points on the line segment E3 in the power line 42a, the closest point to the source line 41a is the point T7, the closest point to the source line 41b is the point T9, and an intermediate point between the point T7 and the point T9 is the point T8. That is, the point T8 is farther from the source line 41a than the point T7 and farther from the source line 41b than the point T9. In this case, the point T8 is farther from the source line (41a or 41b) than the point T7 or T9 on the line segment E3 in the power line 42a. Therefore, as for the points T7 to T9, the resistance of the source layer 41, BSL from the contact CC1 is the highest at the point T8.

FIG. 8 includes graphs illustrating a relation between the resistance of the source layer 41, BSL and the positions of the points T1 to T9. The horizontal axis of graphs GE1 to GE3 represents the positions of the points T1 to T9 on the line segments E1 to E3, and the vertical axis represents a value of resistance of the source layer 41, BSL from the contact CC1 to each of the points T1 to T9.

The graph GE1 indicates the resistance of the source layer 41, BSL from the contact CC1 in FIG. 7 to each of the points T1 to T3 (hereinafter, also the resistance of the source layer 41, BSL at each of the points T1 to T3). A resistance component RR1 is a resistance component of the source layer 41, BSL in the Y-direction from the contact CC1 in FIG. 7 to the position of the line segment E1. A resistance component RL1 is a resistance component of the source layer 41, BSL in the X-direction from the position of the line segment E1 of the source line 41a or 41b to each of the points T1 to T3.

The distance in the Y-direction from the contact CC1 to the position of the line segment E1 is the same at all the points T1 to T3. Therefore, the resistance component RR1 is equal at all the points T1 to T3.

In the X-direction from the position of the line segment E1 of the source line 41a or 41b to the points T1 to T3, no source line 41 made of a metal material is provided between an end of the source line 41 and each of the points T1 to T3. The resistance of the semiconductor source layer BSL is higher than the resistance of the source line 41 made of a metal material. Therefore, on the line segment E1 between an end of the source line 41a or 41b to each of the points T1 to T3, the resistance component RL1 is determined by the resistance of the semiconductor source layer BSL. That is, the resistance component RL1 varies depending on the distance on the line segment E1 from an end of the source line 41a or 41b to each of the points T1 to T3. As a result, the resistance at each of the points T1 to T3 (RR1+RL1) is varied by the resistance component RL1. That is, the resistance of the source layer 41, BSL at each of the points T1 to T3 varies depending on the distance on the line segment E1 from the source line 41a or 41b to each of the points T1 to T3.

Therefore, in the graph GE1, the resistance component RL1 at the point T1 close to the source line 41a and at the point T3 close to the source line 41b is relatively low. Accordingly, the resistance (RR1+RL1) of the source layer 41, BSL at the points T1 and T3 is close to the resistance component RR1 and is relatively low. Meanwhile, the resistance component RL1 at the point T2 farther from the source line 41a than the point T1 and farther from the source line 41b than the point T3 is higher than that at the points T1 and T3. Accordingly, the resistance (RR1+RL1) of the source layer 41, BSL at the point T2 is higher than that at the points T1 and T3. That is, the resistance of the source layer 41, BSL at the point T2 is higher than that at the points T1 and T3 by about the resistance component RL1 of the semiconductor source layer BSL of a length L1 in FIG. 7. In addition, in the Y-direction, the distance R1 from the contact CC1 to the line segment E1 is equal at all the points T1 to T3. Therefore, the resistance component RR1 is added equally and commonly at the points T1 to T3. Accordingly, the resistances (RR1+RL1) of the source layer 41, BSL at the points T1 to T3 form a curve that is close to the resistance component RR1 at the points T1 and T3 and has the maximum value (RR1+RL1) at the point T2.

Voltage drop of a cell source voltage is caused by the resistances at the points T1 to T3. The voltage drop of the cell source voltage is larger as the resistance is higher. Therefore, the voltage drop at the point T2 is larger than that at the points T1 and T3. Accordingly, the voltage drop of the cell source voltage at each of the points T1 to T3 has an identical tendency to the change of the resistance illustrated in the graph GE1.

The graph GE2 in FIG. 8 indicates the resistance of the source layer 41, BSL from the contact CC1 in FIG. 7 to each of the points T4 to T6 (hereinafter, also the resistance of the source layer 41, BSL at each of the points T4 to T6). A resistance component RR2 is a resistance component of the source layer 41, BSL in the Y-direction from the contact CC1 in FIG. 7 to the position of the line segment E2. The resistance component RL1 is a resistance component of the source layer 41, BSL in the X-direction from the position of the line segment E2 of the source line 41a or 41b to each of the points T4 to T6 and is equal to the resistance component RL1 regarding the line segment E1.

In the graph GE2, the resistance component RL1 at the point T4 close to the source line 41a and at the point T6 close to the source line 41b is relatively low, as in the graph GE1. Accordingly, the resistance (RR2+RL1) of the source layer 41, BSL at each of the points T4 and T6 is close to the resistance component RR2 and is relatively low. Meanwhile, the resistance component RL1 at the point T5 farther from the source line 41a than the point T4 and farther from the source line 41b than the point T6 is higher than that at each of the points T4 and T6. Accordingly, the resistance (RR2+RL1) of the source layer 41, BSL at the point T5 is higher than that at each of the points T4 and T6. That is, the resistance of the source layer 41, BSL at the point T5 is higher than that at each of the points T4 and T6 by the resistance component RL1 of the semiconductor source layer BSL of the length L1 in FIG. 7. In addition, in the Y-direction, the distance R2 from the contact CC1 to the line segment E2 is equal at all the points T4 to T6. Therefore, the resistance component RR2 is added equally and commonly at the points T4 to T6. Accordingly, the resistances (RR2+RL1) of the source layer 41, BSL form a curve that is close to the resistance component RR2 at the points T4 and T6 and becomes maximum at the point T5.

The line segment E2 is farther from the contact CC1 than the line segment E1. Therefore, the resistance component RR2 is higher than the resistance component RR1 by a resistance dRR2 of the source line 41 corresponding to a difference between the distance from the contact CC1 to the line segment E1 and the distance from the contact CC1 to the line segment E2. That is, the resistance component RR2 is the resistance component RR1+dRR2.

Voltage drop of the cell source voltage at each of the points T4 to T6 has an identical tendency to the change of the resistance illustrated in the graph GE2.

Next, the graph GE3 in FIG. 8 indicates the resistance of the source layer 41, BSL from the contact CC1 in FIG. 7 to each of the points T7 to T9 (hereinafter, also the resistance of the source layer 41, BSL at each of the points T7 to T9). A resistance component RR3 is a resistance component of the source layer 41, BSL from the contact CC1 in FIG. 7 to the line segment E3. The resistance component RL1 is a resistance component of the source layer 41, BSL in the X-direction from the position on the line segment E3 of the source line 41a or 41b to each of the points T7 to T9, and is equal to the resistance component RL1 regarding the line segment E1 or E2.

In the graph GE3 in FIG. 8, the resistance component RL1 at the point T7 close to the source line 41a and at the point T9 close to the source line 41b is relatively low, as in the graphs GE1 and GE2. Accordingly, the resistance (RR3+RL1) of the source layer 41, BSL at each of the points T7 and T9 is close to the resistance component RR3 and is relatively low. Meanwhile, the resistance component RL1 at the point T8 farther from the source line 41a than the point T7 and farther from the source line 41b than the point T9 is higher than that at each of the points T7 and T9. Accordingly, the resistance (RR3+RL1) of the source layer 41, BSL at the point T8 is higher than that at each of the points T7 and T9. That is, the resistance of the source layer 41, BSL at the point T8 is higher than that at each of the points T7 and T9 by the resistance component RL1 of the semiconductor source layer BSL of the length L1 in FIG. 7. In addition, in the Y-direction, the distance R3 from the contact CC1 to the line segment E3 is equal at all the points T7 to T9. Therefore, the resistance component RR3 is added equally and commonly at the points T7 to T9. Accordingly, the resistances (RR3+RL1) of the source layer 41, BSL form a curve that is close to RR3 at the points T7 and T9 and becomes maximum at the point T8.

The line segment E3 is farther from the contact CC1 than the line segment E1. Therefore, the resistance component RR3 is higher than the resistance component RR1 by a resistance dRR3 of the source line 41 corresponding to a difference between the distance from the contact CC1 to the line segment E1 and the distance from the contact CC1 to the line segment E3. That is, the resistance component RR3 is the resistance component RR1+dRR3.

Voltage drop of the cell source voltage at each of the points T7 to T9 has an identical tendency to the change of the resistance illustrated in the graph GE3.

In the present embodiment, the source lines 41 and the power lines 42 are formed by processing the same metal layer. Accordingly, the metal layer provided on the semiconductor source layer BSL can be used not only for the source lines 41 but also for the power lines 42.

However, the source lines 41 are not provided above the entire semiconductor source layer BSL, but are locally provided. In this case, the resistance of the source layer 41, BSL becomes higher than in a case where the source lines 41 are provided above the entire semiconductor source layer BSL, which can cause voltage drop of the cell source voltage.

Meanwhile, the source lines 41 and the power lines 42 are alternately provided on the semiconductor source layer BSL in the present embodiment. Accordingly, the source lines 41 can be arranged on the semiconductor source layer BSL substantially evenly and connected thereto. Therefore, the resistance of the source layer 41, BSL in the present embodiment does not increase much as compared with the case where the source lines 41 are provided above the entire semiconductor source layer BSL.

Further, it is unnecessary to stack a metal layer for the source lines 41 and a metal layer for the power lines 42 in separate steps because the source lines 41 and the power lines 42 are formed by the same metal layer, so that a manufacturing process of a semiconductor device is shortened. Further, since it is unnecessary to stack the source line 41 and the power lines 42, the number of stacked wiring layers can be reduced.

Furthermore, the source line 41 is not provided in a portion where the power lines 42 are provided. Therefore, the resistance of the source layer 41, BSL from the contact CC1 to each of the points T2, T5, and T8 that are intermediate points in the power line 42 becomes high.

Meanwhile, in the present embodiment, the source lines 41 and the power lines 42 are alternately arranged on the semiconductor source layer BSL, whereby the width of each power line 42 (the interval between the source lines 41 adjacent to each other) is made small. Accordingly, increase in the resistance of the source layer 41, BSL from the contact CC1 to each of the points T2, T5, and T8 can be suppressed. When the width of the power line 42 is made small and the number of the power lines 42 is increased, increase in the resistance of the source layer 41, BSL from the contact CC1 to each of the points T2, T5, and T8 can be further suppressed.

### Second Embodiment

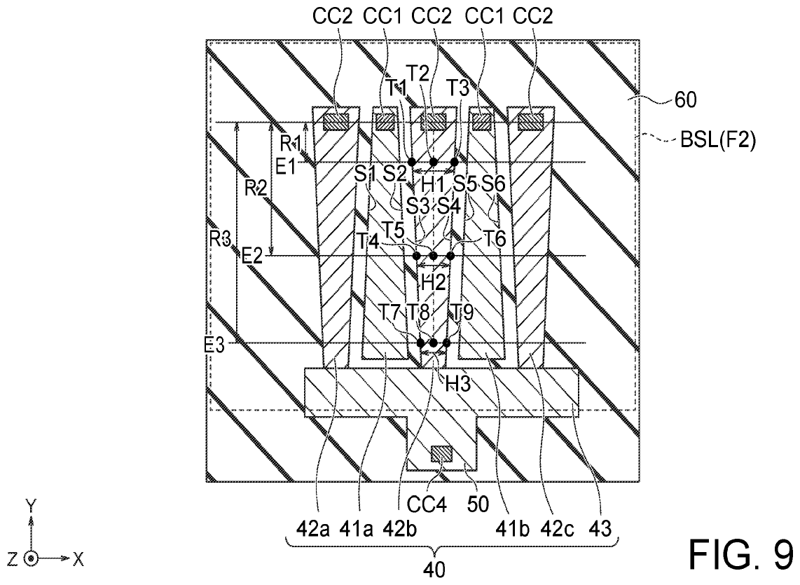

FIG. 9 is a schematic plan view illustrating the source lines 41, the power lines 42, and the contacts CC1 of the semiconductor device 1 according to a second embodiment. The second embodiment is different from the first embodiment in the planar shape of the metal layer 40 (the source lines 41 and the power lines 42), but the rest of the configuration in the second embodiment may be identical to that in the first embodiment.

In the second embodiment, sides S1 and S2 of the source line 41a are inclined with respect to the Y-direction in such a manner that, in the planar shape of the source line 41a, the width in the X-direction of the source line 41a increases with increase in the distance from the contact CC1. Meanwhile, sides S3 and S4 of the power line 42b are inclined with respect to the Y-direction in such a manner that, in the planar shape of the power line 42b, the width in the X-direction of the power line 42b decreases with increase in the distance from the contact CC2. Therefore, the width in the X direction of the power line 42b becomes smaller in the order of a width H1, a width H2, and a width H3 as the distance from the contact CC2 increases. Other source lines including the source line 41b have a planar shape identical to that of the source line 41a. Other power lines including the power line 42a and a power line 42c have a planar shape identical to that of the power line 42b.

As described above, the source lines 41 and the power lines 42 have planar shapes complementary to each other and are alternately arranged in the X-direction so as not to be in contact with each other.

The resistance from the contact CC1 increases with increase in the distance in the Y-direction from the contact CC1, so that voltage drop increases. Therefore, the resistance component RR2 from the contact CC1 to the line segment E2 is higher than the resistance component RR1 from the contact CC1 to the line segment E1. The resistance component RR3 from the contact CC1 to the line segment E3 is higher than the resistance component RR2 from the contact CC1 to the line segment E2. Meanwhile, the width in the X-direction of the source line 41 increases as the distance from the contact CC1 increases. Therefore, a resistance component RH1 of the source layer 41, BSL from the source line 41a or 41b on the line segment E1 to the point T2 is higher than a resistance component RH2 of the source layer 41, BSL from the source line 41a or 41b on the line segment E2 to the point T5. The resistance component RH2 of the semiconductor source layer BSL from the source line 41a or 41b on the line segment E2 to the point T5 is higher than the resistance component RH3 of the semiconductor source layer BSL from the source line 41a or 41b on the line segment E3 to the point T8. Accordingly, variation of the resistances of the source layer 41, BSL from the contact CC1 to the points T1 to T9 (RR1+RH1, RR2+RH2, and RR3+RH3) can be reduced.

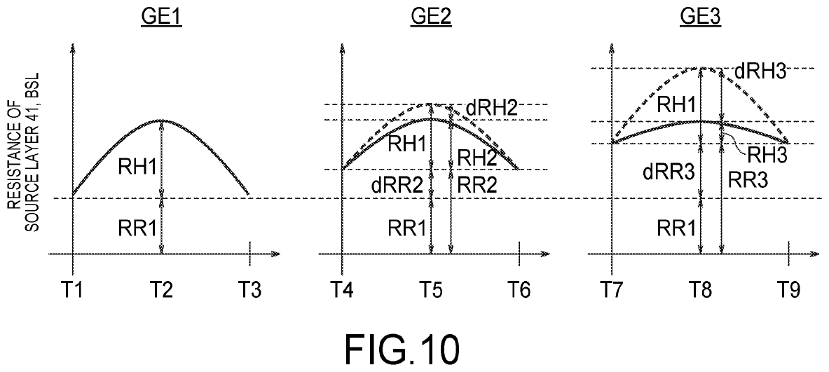

FIG. 10 includes graphs illustrating a relation between the resistance of the source layer 41, BSL and the positions of the points T1 to T9. The horizontal axis of the graphs GE1 to GE3 represents the positions of the points T1 to T9 on the line segments E1 to T3, and the vertical axis represents a resistance value of the source layer 41, BSL.

The graph GE1 in FIG. 10 indicates change of the resistance of the source layer 41, BSL on the line segment E1 (at the points T1 to T3).

As in the first embodiment, the resistance component RH1 at the point T1 close to the source line 41a and at the point T3 close to the source line 41b is relatively low. Accordingly, the resistance (RR1+RH1) of the source layer 41, BSL at each of the points T1 and T3 is close to the resistance component RR1 and is relatively low. Meanwhile, the resistance component RH1 at the point T2 farther from the source line 41a than the point T1 and farther from the source line 41b than the point T3 is higher than that at each of the points T1 and T3. Accordingly, the resistance (RR1+RH1) of the source layer 41, BSL at the point T2 is higher than that at each of the points T1 and T3. Consequently, the graph GE1 has a tendency identical to that in the GE1 in FIG. 8, and the resistances (RR1+RH1) of the source layer 41, BSL form a curve that is close to the resistance component RR1 at each of the points T1 and T3 and has the maximum value (RR1+RH1) at the point T2. The resistance component RR1 is the same as the resistance component RR1 in the first embodiment.

The graph GE2 indicates the resistance of the source layer 41, BSL from the contact CC1 in FIG. 9 to each of the points T4 to T6.

Here, as illustrated in FIG. 9, the width from an end of the source line 41a or 41b on the line segment E2 to the point T5 is smaller than the width from an end of the source line 41a or 41b on the line segment E1 to the point T2. Therefore, the resistance component RH2 of the source layer 41, BSL from the end of the source line 41a or 41b on the line segment E2 to the point T5 is lower than the resistance component RH1 of the source layer 41, BSL from the end of the source line 41a or 41b on the line segment E1 to the point T2. That is, the maximum value of the resistance component RH2 of the source layer 41, BSL at the point T5 is lower than the maximum value of the resistance component RH1 at the point T2 by a resistance component dRH2 corresponding to a difference between the width from an end of the source line 41a or 41b on the line segment E2 to the point T5 and the width from an end of the source line 41a or 41b on the line segment E1 to the point T2. Accordingly, the resistance (RR2+RH2) of the source layer 41, BSL at the point T5 is higher than that at each of the points T4 and T6, but is not much different from the resistance (RR1+RH1) at the point T2. The resistance component RR2 is the same as the resistance component RR2 in the first embodiment and is the resistance component RR1+dRR2.

The graph GE3 indicates the resistance of the source layer 41, BSL from the contact CC1 in FIG. 9 to each of the points T7 to T9.

Here, as illustrated in FIG. 9, the width from an end of the source line 41a or 41b on the line segment E3 to the point T8 is smaller than each of the width from an end of the source line 41a or 41b on the line segment E2 to the point T5 and the width from an end of the source line 41a or 41b on the line segment E1 to the point T2. Therefore, the resistance component RH3 of the source layer 41, BSL from the end of the source line 41a or 41b on the line segment E3 to the point T8 is lower than each of the resistance components RH1 and RH2. For example, the maximum value of the resistance component RH3 of the source layer 41, BSL at the point T8 is lower than the maximum value of the resistance component RH1 at the point T1 by a resistance component dRH3 corresponding to a difference between the width from an end of the source line 41a or 41b on the line segment E1 to the point T2 and the width from an end of the source line 41a or 41b on the line segment E3 to the point T8. Accordingly, the maximum value of the resistance (RR3+RH3) of the source layer 41, BSL at the point T8 is higher than that at each of the points T7 and T9, but is not much different from the maximum value of the resistance (RR1+RH1 or RR2+RH2) at the point T1 or T2. The resistance component RR3 is the same as the resistance component RR3 in the first embodiment and is the resistance component RR1+dRR3.

As described above, according to the second embodiment, the source line 41 is narrow near the contact CC1 (a cell source driver) and becomes wider as it becomes farther from the contact CC1. Accordingly, although the points T2, T5, and T8 are different from one another in distance in the Y-direction from the contact CC1, the resistances of the source layer 41, BSL from the contact CC1 to the points T2, T5, and T8 are not much different from one another or can be made substantially the same as one another. Accordingly, voltage variation at any position in the source layer 41, BSL can be reduced.

The rest of the configuration in the second embodiment may be identical to that in the first embodiment. Accordingly, the second embodiment can also obtain the effects of the first embodiment.

### Third Embodiment

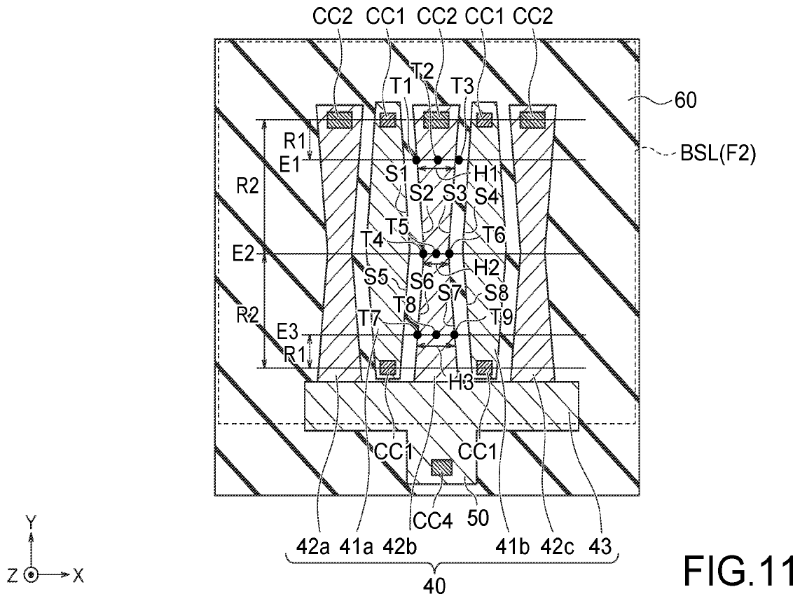

FIG. 11 is a schematic plan view illustrating the source lines 41, the power lines 42, and the contacts CC1 of the semiconductor device 1 according to a third embodiment. The third embodiment is different from the first embodiment in the planar shape of the metal layer 40 (the source lines 41 and the power lines 42). Further, the third embodiment is different from the first embodiment in including the contacts CC1 at both ends of the source line 41.

In the third embodiment, the source line 41a is connected to the contacts CC1 (cell source drivers) at both ends in the Y-direction. Further, the source line 41a has such a planar shape that the width in the X-direction increases from both ends in the Y-direction toward the center. Therefore, the width in the X-direction of the source line 41a is largest at the center in the longitudinal direction (the Y-direction). It suffices that the width in the X-direction of the source line 41a on the line segment E1 and that on the line segment E3 are the same as each other. Further, the source line 41a and the source line 41b have an identical planar shape.

Meanwhile, the width in the X-direction of the power line 42b decreases from both ends (the contacts CC1 or the power line 43) in the Y-direction of the power line 42b toward the center. Therefore, the width in the X-direction of the power line 42b is smallest at the center in the longitudinal direction (the Y-direction). For example, the width H2 of the power line 42b at the center is smaller than the width H1 and the width H3 at both ends thereof. It suffices that the width in the X-direction of the power line 42b on the line segment E1 and that on the line segment E3 are the same as each other. Further, the power lines 42a to 42c have an identical planar shape. The power lines 42a and 42c have a planar shape identical to that of the power line 42b. As described above, the source lines 41 and the power lines 42 have planar shapes complementary to each other and are alternately arranged in the X-direction so as not to be in contact with each other.

Sides 51 and S5 of the source line 41a are inclined with respect to the Y-direction in such a manner that, in the planar shape of the source line 41a, the width in the X-direction of the source line 41a increases with increase in the distance from the contact CC1 in the Y-direction, and becomes the maximum at the center. Further, sides S2 and S6 of the power line 42b are inclined with respect to the Y-direction in such a manner that, in the planar shape of the power line 42b, the widths H1 and H3 of the power line 42b in the X-direction are the largest while the width H2 is the smallest.

As the distance from the contact CC1 at each end in the Y-direction of the source line 41a or 41b increases in the Y-direction, the resistance from the contact CC1 increases, so that voltage drop increases. Therefore, the resistance component RR2 of the source line 41a or 41b from the contact CC1 to the line segment E2 is higher than the resistance component RR1 from the contact CC1 to the line segment E1 or E3. Meanwhile, the width in the X-direction of the source line 41a or 41b increases as the distance from the contact CC1 at each end increases. Therefore, the resistance component RH1 or RH3 of the semiconductor source layer BSL from the source line 41a or 41b on the line segment E1 or E3 to the point T2 or T8 is higher than the resistance component RH2 from the source line 41a or 41b on the line segment E2 to the point T5.

The source lines 41a and 41b each have the contacts CC1 at both ends in the longitudinal direction. Therefore, the intermediate portion in the longitudinal direction of the source line 41a or 41b is the farthest from the contact CC1, and the resistance of the source layer 41, BSL is the highest there. Therefore, according to the third embodiment, the resistance of the source layer 41, BSL (RR2+RH2) from the contact CC1 to the point T5 on the line segment E2 at the center of the source line 41a or 41b is lowered, whereby variations of the resistances of the source layer 41, BSL from the contact CC1 to each of the points T1 to T9 can be reduced.

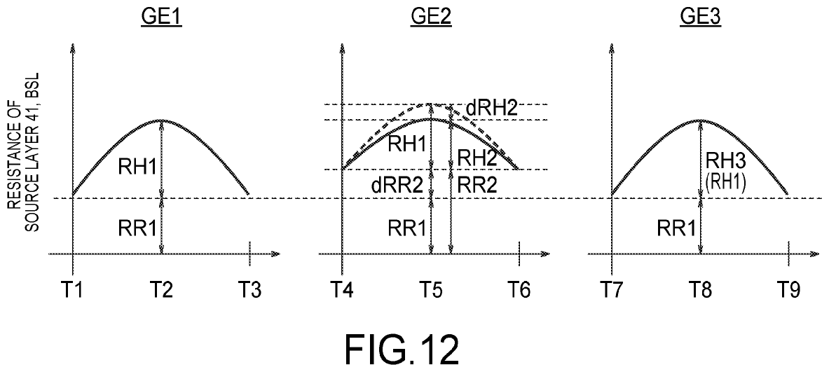

FIG. 12 includes graphs illustrating a relation between the resistance of the source layer 41, BSL and the positions of the points T1 to T9. The horizontal axis of graphs GE1 to GE3 represents the positions of the points T1 to T9 on the line segments E1 to T3, and the vertical axis represents a resistance value of the source layer 41, BSL.

The graph GE1 indicates change of the resistance of the source layer 41, BSL on the line segment E1 (at the points T1 to T3). The resistance of the source layer 41, BSL on the line segment E1 according to the third embodiment is identical to the resistance of the source layer 41, BSL on the line segment E1 according to the second embodiment (the graph GE1 in FIG. 10), and therefore its detailed descriptions are omitted.

The graph GE2 indicates change of the resistance of the source layer 41, BSL on the line segment E2 (at the points T4 to T6). The change of the resistance of the source layer 41, BSL on the line segment E2 according to the third embodiment is substantially identical to the change of the resistance of the source layer 41, BSL on the line segment E2 according to the second embodiment (the graph GE2 in FIG. 10). However, according to the third embodiment, the contacts CC1 are provided at both ends of the source line 41a. Therefore, the resistances of or voltage drop in the source layer 41, BSL from the contact CC1 to the points T4 to T6 in the third embodiment can be made lower than the resistances of or voltage drop in the source layer 41, BSL at the points T4 to T6 in the second embodiment.

The graph GE3 indicates the resistance of the source layer 41, BSL from the contact CC1 in FIG. 11 to each of the points T7 to T9. In the third embodiment, the contacts CC1 are provided at both ends of each of the source lines 41a and 41b. The distance from the contact CC1 at the upper end of the source line 41a or 41b to the line segment E1 and the distance from the contact CC1 at the lower end of the source line 41a or 41b to the line segment E3 are both the distance R1, i.e., equal to each other. Further, the width H1 and the width H3 are substantially the same as each other. Therefore, the distance from the source line 41a or 41b to each of the points T1 to T3 is substantially equal to the distance from the source line 41a or 41b to each of the points T7 to T9. Therefore, the resistance (RR1+RL3) of the source layer 41, BSL from the contact CC1 to each of the points T7 to T9 is substantially equal to the resistance (RR1+RL1) of the source layer 41, BSL from the contact CC1 to each of the points T1 to T3. Accordingly, the graphs GE1 and GE3 in FIG. 12 have an identical tendency.

As described above, according to the third embodiment, the contacts CC1 are provided at both ends of each source line 41, respectively. Therefore, each source line 41 is connected to cell source drivers at both ends, so that voltage drop of a cell source voltage in the source layer 41, BSL can be reduced. Further, the width H1 and the width H3 at both ends of the source line 41 are substantially the same as each other. Accordingly, the resistance (RR1+RH1) of the source layer 41, BSL from the contact CC1 to each of the points T1 to T3 at one end of the power line 42 becomes substantially equal to the resistance (RR1+RH3) of the source layer 41, BSL from the contact CC1 to each of the points T7 to T9 at the other end of the power line 42.

Further, the source line 41 is narrow near the contact CC1 provided at each end in its longitudinal direction, and gradually becomes wider from the contact CC1 toward the center. Accordingly, the resistance component RH2 at the center of the source line 41 is lower than the resistance components RH1 and RH3 at both ends of the source line 41. Consequently, although the point T5 is different from the points T2 and T8 in distance in the Y-direction from the contact CC1, the resistance of the source layer 41, BSL from the contact CC1 to the point T5 is not much different from the resistance of the source layer 41, BSL from the contact CC1 to the point T2 or T8 or can be made substantially equal. Accordingly, voltage variation at any position in the source layer 41, BSL can be reduced.

The rest of the configuration in the third embodiment may be identical to that in the first embodiment. Accordingly, the third embodiment can also obtain the effects of the first embodiment.

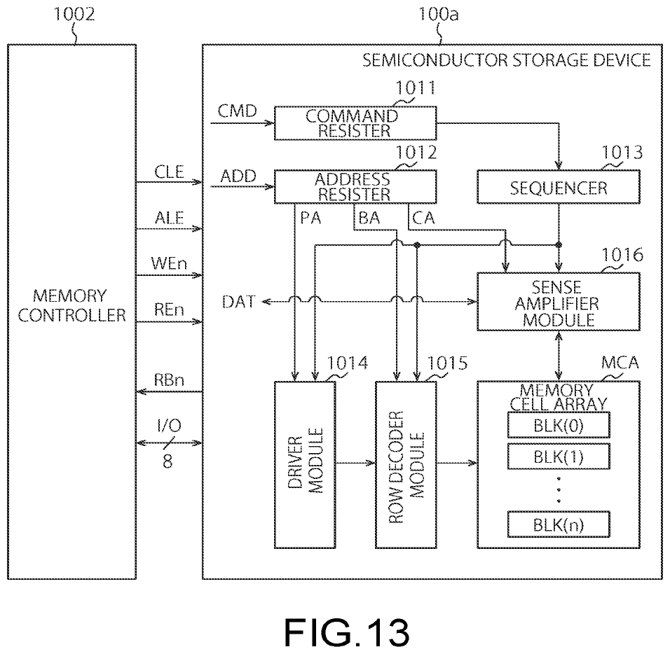

FIG. 13 is a block diagram illustrating a configuration example of a semiconductor device to which any of the above embodiments is applied. The semiconductor device 1 is, for example, a semiconductor storage device 100a, such as a NAND flash memory, that can store data therein in a non-volatile manner, and is controlled by an external memory controller 1002. Communication between the semiconductor storage device 100a and the memory controller 1002 supports, for example, a NAND interface standard.

As illustrated in FIG. 13, the semiconductor storage device 100a includes, for example, a memory cell array MCA, a command resister 1011, an address resister 1012, a sequencer 1013, a driver module 1014, a row decoder module 1015, and a sense amplifier module 1016.

The memory cell array MCA includes a plurality of blocks BLK(0) to BLK(n) (n is an integer of 1 or more). Each block BLK is a set of a plurality of memory cells capable of storing therein data in a non-volatile manner and is used as, for example, the unit of erasing data. Further, the memory cell array MCA is provided with a plurality of bit lines and a plurality of word lines. Each memory cell is associated with one bit line and one word line, for example. The detailed configuration of the memory cell array MCA will be described later.

The command resister 1011 retains a command CMD the semiconductor storage device 100a has received from the memory controller 1002. The command CMD includes, for example, an instruction to cause the sequencer 1013 to perform a read operation, a write operation, an erase operation, or the like.

The address resister 1012 retains address information ADD the semiconductor storage device 100a has received from the memory controller 1002. The address information ADD includes, for example, a block address BA, a page address PA, and a column address CA. For example, the block address BA, the page address PA, and the column address CA are used for selecting the blocks BLK, the word lines, and the bit lines, respectively.

The sequencer 1013 controls the operation of the entire semiconductor storage device 100a. For example, the sequencer 1013 controls the driver module 1014, the row decoder module 1015, the sense amplifier module 1016, and the like based on the command CMD retained in the command resister 1011 to perform a read operation, a write operation, an erase operation, or the like.

The driver module 1014 generates a voltage to be used in a read operation, a write operation, an erase operation, or the like. The driver module 1014 then applies the generated voltage to a signal line corresponding to a selected word line based on, for example, the page address PA retained in the address register 1012.

The row decoder module 1015 includes a plurality of row decoders. The row decoder selects, based on the block address BA retained in the address resister 1012, one block BLK in the memory cell array MCA corresponding to that address. The row decoder then transfers, for example, the voltage applied to the signal line corresponding to the selected word line to the selected word line in the selected block BLK.

The sense amplifier module 1016 applies a desired voltage to each bit line in accordance with write data DAT received from the memory controller 1002 in a write operation. Further, in a read operation, the sense amplifier module 1016 determines data stored in a memory cell based on a voltage of a bit line, reads out the determination result, and transfers the determination result as data DAT to the memory controller 1002.

The semiconductor storage device 100a and the memory controller 1002 described above may be combined with each other to constitute one semiconductor device. Examples of such a semiconductor device include a memory card such an SD™ card, and an SSD (solid state drive).

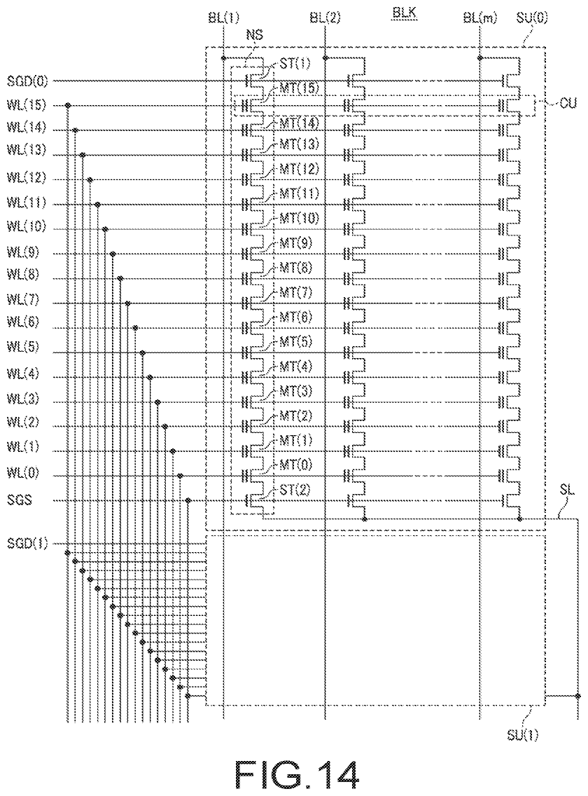

FIG. 14 is a circuit diagram illustrating an example of a circuit configuration of the memory cell array MCA. One block BLK is extracted from the blocks BLK included in the memory cell array MCA. As illustrated in FIG. 14, the block BLK includes a plurality of string units SU(0) to SU(k) (k is an integer of 1 or more).

Each string unit SU includes a plurality of NAND strings NS respectively associated with bit lines BL(0) to BL(m) (m is an integer of 1 or more). Each NAND string NS includes, for example, memory cell transistors MT(0) to MT(15) and selection transistors ST(1) and ST(2). The memory cell transistor MT includes a control gate and a charge storage layer and retains data in a non-volatile manner. Each of the selection transistors ST(1) and ST(2) is used for selecting the string units SU in various operations.

In each NAND string NS, the memory cell transistors MT(0) to MT(15) are connected in series. A drain of the selection transistor ST(1) is connected to a bit line BL associated therewith, and a source of the selection transistor ST(1) is connected to one end of the memory cell transistors MT(0) to MT(15) connected in series. A drain of the selection transistor ST(2) is connected to the other end of the memory cell transistors MT(0) to MT(15) connected in series. A source of the selection transistor ST(2) is connected to a source line SL.

In the same block BLK, the control gates of the memory cell transistors MT(0) to MT(15) are connected in common to word lines WL(0) to WL(15). Gates of the selection transistors ST(1) in each of the string units SU(0) to SU(k) are connected in common to a corresponding one of selection gate lines SGD(0) to SGD(k). Gates of the selection transistors ST(2) are connected in common to a selection gate line SGS.

In the circuit configuration of the memory cell array MCA described above, each bit line BL is shared by the NAND strings NS, to which the same column address is assigned, in each string unit SU. The source line SL is shared by, for example, the blocks BLK.

A set of the memory cell transistors MT connected to the common word line WL in one string unit SU is referred to as, for example, a cell unit CU. For example, the storage capacity of the cell unit CU including the memory cell transistors MT each storing therein 1-bit data is defined as “1-page data”. The cell unit CU can have a storage capacity of 2-page data or more in accordance with the number of bits of data stored in the memory cell transistors MT.

The memory cell array MCA included in the semiconductor storage device 100a according to the present embodiment is not limited to the circuit configuration described above. For example, the number of the memory cell transistors MT and the number of the selection transistors ST(1) and ST(2) included in each NAND string NS can be designed to be any number. The number of the string units SU included in each block BLK can be designed to be any number.

### (Modification)

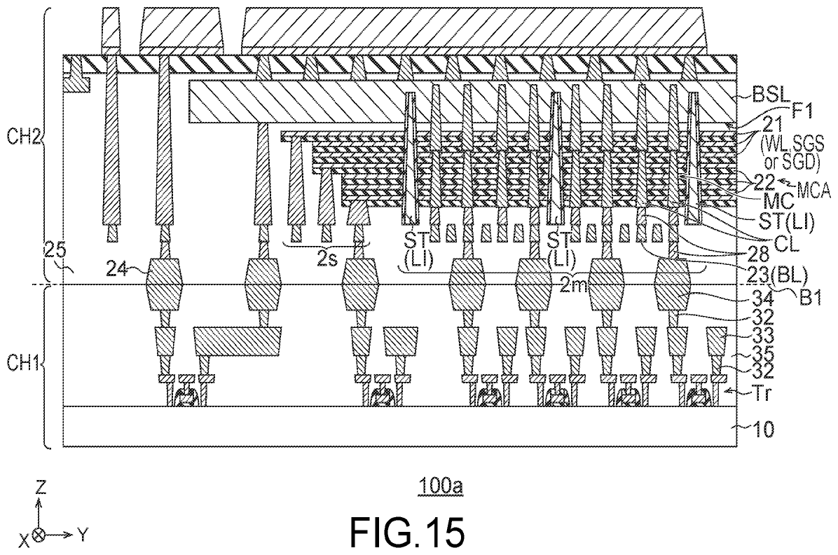

FIG. 15 is a cross-sectional view illustrating another configuration example of the semiconductor storage device 100a. The semiconductor storage device 100a includes a memory chip CH2 having a memory cell array and a controller chip CH1 having a CMOS circuit. The memory chip CH2 and the controller chip CH1 are bonded together at the bonding surface B1 at which they are electrically connected to each other via the wires 24 and 34 joined to each other. FIG. 15 illustrates a state where the memory chip CH2 is placed on the controller chip CH1.

The configurations of the memory cell array MCA of the memory chip CH2 and the CMOS circuit may be identical to those of the embodiments described above, respectively.

In the present modification, the memory chip CH2 and the controller chip CH1 are formed separately and these chips are bonded together at the bonding surface B1.

In the controller chip CH1, the vias 32 and the wires 33 and 34 are provided above a transistor Tr. The wires 33 and 34 constitute a multilayer wiring structure in the interlayer dielectric film 35. The wires 34 are embedded in the interlayer dielectric film 35 and exposed in a surface of the interlayer dielectric film 35 to be substantially flush therewith. The wires 33 and 34 are electrically connected to the transistor Tr and the like. A low-resistance metal, such as copper and tungsten, is used for the vias 32 and the wires 33 and 34. The interlayer dielectric film 35 covers and protects the transistors Tr, the vias 32, and the wires 33 and 34. An insulating film, such as a silicon oxide film, is used as the interlayer dielectric film 35.

In the memory chip CH2, the vias 28 and the wires 23 and 24 are provided below the memory cell array MCA. The wires 23 and 24 constitute a multilayer wiring structure in the interlayer dielectric film 25. The wire 24 is embedded in the interlayer dielectric film 25 and is exposed in a surface of the interlayer dielectric film 25 to be substantially flush therewith. The wires 23 and 24 are electrically connected to, for example, the semiconductor bodies 210 of the column portions CL. A low-resistance metal, such as copper and tungsten, is used for the vias 28 and the wires 23 and 24. The interlayer dielectric film 25 covers and protects the stack 20, the vias 28, and the wires 23 and 24. An insulating film, such as a silicon oxide film, is used as the interlayer dielectric film 25.

The interlayer dielectric film 25 and the interlayer dielectric film 35 are bonded together at the bonding surface B1, and the wires 24 and 34 are also joined together at the bonding surface B1 to be substantially flush therewith. Accordingly, the memory chip CH2 and the controller chip CH1 are electrically connected to each other via the wires 24 and 34.

As described above, the present modification can be applied to a semiconductor device in which the memory chip CH2 and the controller chip CH1 are bonded together.

### Fourth Embodiment

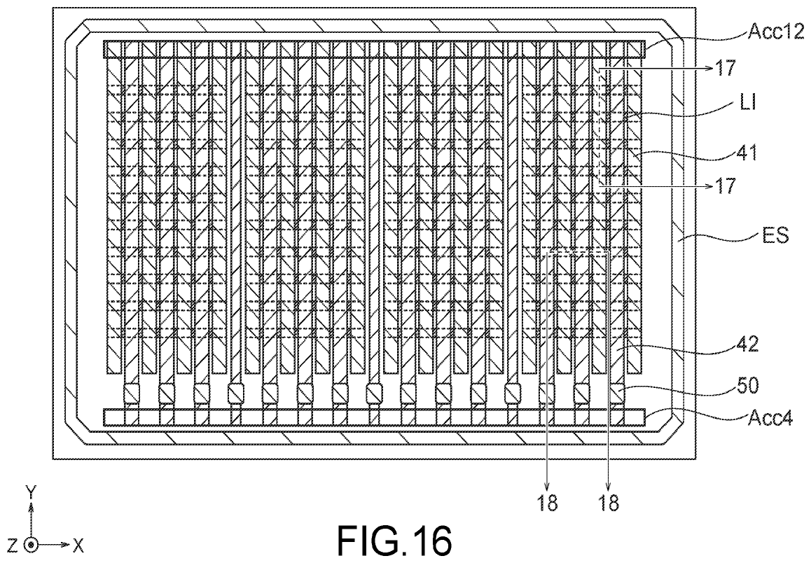

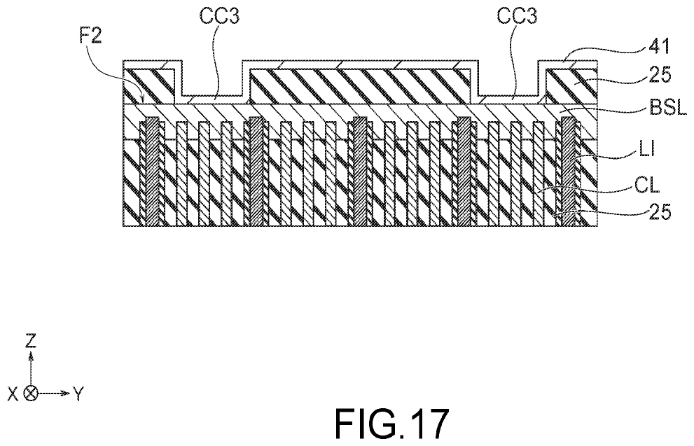

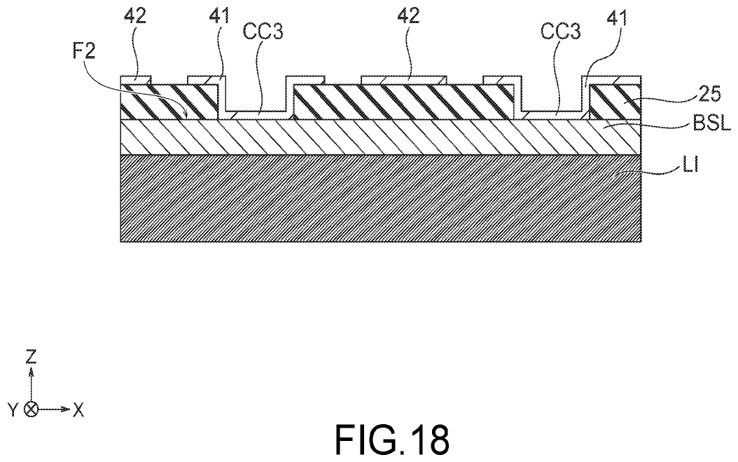

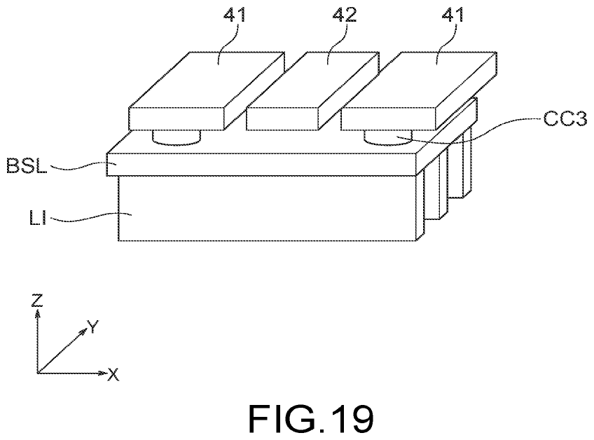

FIG. 16 is a plan view illustrating a configuration example of the semiconductor device 1 according to a fourth embodiment. FIG. 16 illustrates a plane of the entire memory chip CH2. FIGS. 17 and 18 are cross-sectional views illustrating the configuration example of the semiconductor device 1 according to the fourth embodiment. FIG. 17 illustrates a cross-section along a line 17-17 in FIG. 16, and FIG. 18 illustrates a cross-section along a line 18-18 in FIG. 16. FIG. 19 is a perspective view illustrating the configuration example of the semiconductor device 1 according to the fourth embodiment.

In the fourth embodiment, the slits ST (LI) are constituted by the source wires LI. As illustrated in FIG. 16, the source wires LI extend in a direction crossing the source lines 41 and the power lines 42 and 43 (e.g., substantially perpendicular direction) in plan view as viewed from the Z-direction. The source wires LI are each divided into four in the X-direction to correspond four planes of the memory cell array MCA, respectively. A region Acc4 is a region where the contact CC4 is provided. A region Acc12 is a region where the contacts CC1 and CC2 are provided. An edge seal ES is provided on an outer edge of the memory chip CH2 in order to prevent crack or separation from outside.

As illustrated in FIG. 17, the source wires LI are configured in such a manner that the inner wall of the slit is covered with an insulating film, such as a silicon oxide film, and a conductive material is further embedded inside the insulating film. The source wires LI are each connected to the semiconductor source layer BSL at one end and to another wire at the other end. Accordingly, the source wire LI can supply a source voltage to the source lines 41 via the semiconductor source layer BSL.

In the present embodiment, as illustrated in FIG. 18, the source lines 41 and the power lines 42 are alternately arranged in the X-direction on the second surface F2 side. The source lines 41 and the power lines 42 extend in the Y-direction substantially parallel to each other as illustrated in FIGS. 16 and 17. Each source line 41 is electrically connected to the semiconductor source layer BSL by the contact CC3.

The source wires LI extend in a direction crossing the source lines 41 and the power lines 42 (e.g., substantially perpendicular direction) in plan view as viewed from the Z-direction. That is, the source wires LI extend in the direction in which the source lines 41 and the power lines 42 are arranged (the X-direction) in plan view as viewed from the Z-direction. Further, the source wires LI are alternately arranged in the extending direction of the source lines 41 and the power lines 42 (the Y-direction) in plan view as viewed from the Z-direction.

As illustrated in FIG. 17, in the extending direction of the source lines 41 (the Y-direction), the power line 42 is not provided to be adjacent to the source line 41. Therefore, the interval between the contacts CC3 adjacent to each other can be made smaller. By making the interval between the adjacent contacts CC3 smaller, the resistance of contact between the source wire 41 and the semiconductor source layer BSL can be reduced. Accordingly, the resistance of the semiconductor source layer BSL can be reduced by adjusting the interval between the adjacent contacts CC3.

Meanwhile, as illustrated in FIGS. 18 and 19, in the direction in which the source lines 41 and the power lines 42 are arranged (the X-direction), the power lines 42 are provided on both sides of the source line 41 to be adjacent to the source line 41. Therefore, there is a limit on reducing the interval between the source lines 41 adjacent to each other. Therefore, in the X-direction, it is difficult to reduce the resistance of contact between the source line 41 and the semiconductor source layer BSL by adjusting the intervals between the adjacent source lines 41 or the intervals between the adjacent contacts CC3.

Accordingly, in the fourth embodiment, the source wires LI extend in the direction crossing the source lines 41 and the power lines 42 (e.g., substantially perpendicular direction) in plan view as viewed from the Z-direction. Accordingly, as illustrated in FIG. 18, the source wires LI are in contact with the semiconductor source layer BSL at their entire bottom surfaces in the X-direction. The contacts CC3 adjacent to each other in the X-direction are electrically connected not only via the semiconductor source layer BSL but also via the source wire LI below the semiconductor source layer BSL. Therefore, the resistance of the contacts CC3 adjacent to each other in the X-direction is reduced. That is, according to the fourth embodiment, the resistance of the semiconductor source layer BSL is reduced by making the interval between the adjacent contacts CC3 smaller in the Y-direction. In the X-direction, the resistance of the semiconductor source layer BSL is reduced by the source wire LI. Accordingly, the resistance of the semiconductor source layer BSL can be reduced to the same level as that in a case where the source lines 41 are provided on the entire semiconductor source layer BSL. Therefore, it is possible to prevent the source voltage from being changed to an unintended potential.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a plurality of transistors;
a memory cell array provided above the transistors;
a first semiconductor layer provided above the memory cell array and having a first surface located on a side on which the memory cell array is provided and a second surface opposite to the first surface;
a first metal wire provided above the second surface and electrically connected to the first semiconductor layer;
a second metal wire provided above the second surface to be present in a same layer as the first metal wire and not to be in contact with the first metal wire and the first semiconductor layer;
a first contact provided below the first metal wire, extending in a first direction from the first surface to the second surface, and configured to electrically connect one of the transistors to the first metal wire; and
a second contact provided below the second metal wire, extending in the first direction, and configured to electrically connect another one of the transistors to the second metal wire.

2. The device of claim 1, further comprising a first insulation layer provided on the first semiconductor layer, wherein
a plurality of the second metal wires are provided on the first insulation layer and electrically isolated from the first semiconductor layer by the first insulation layer.

3. The device of claim 1, further comprising a first insulation layer provided on the first semiconductor layer, wherein
a plurality of the first metal wires are provided on the first insulation layer and electrically connected to the first semiconductor layer via a plurality of third contacts provided in the first insulation layer.

4. The device of claim 1, wherein the first metal wires and the second metal wires extend in a second direction parallel to the second surface.

5. The device of claim 2, wherein the first metal wires and the second metal wires extend in a second direction parallel to the second surface.

6. The device of claim 3, wherein the first metal wires and the second metal wires extend in a second direction parallel to the second surface.

7. The device of claim 4, wherein, in plan view as viewed from the first direction,
the first metal wires and the second metal wires are alternately arranged in a third direction that crosses the first and second directions at substantially right angles.

8. The device of claim 7, further comprising a first electrode provided above the second surface and electrically isolated from the first semiconductor layer, wherein
the second metal wires are electrically connected to the first electrode.

9. The device of claim 8, further comprising a fourth contact provided to extend in the first direction and connected between the first electrode and a third one of the transistors.

10. The device of claim 9, wherein, in plan view as viewed from the first direction,
the first metal wires each have a rectangular shape with its longitudinal direction along the second direction, and
each of the second metal wires extends between the first metal wires and electrically connects the second contact and the fourth contact to each other.

11. The device of claim 10, wherein, in plan view as viewed from the first direction,
sides of the first metal wires, facing the second metal wires, are inclined with respect to the second direction, and
sides of the second metal wires, facing the first metal wires, are inclined with respect to the second direction.

12. The device of claim 10, wherein, in plan view as viewed from the first direction,
a width of each of the first metal wires in a third direction crossing the first and second directions at substantially right angles becomes larger with increase in a distance from the first contact in the second direction.

13. The device of claim 11, wherein, in plan view as viewed from the first direction,
a width of each of the first metal wires in a third direction crossing the first and second directions at substantially right angles becomes larger with increase in a distance from the first contact in the second direction.

14. The device of claim 10, wherein, in plan view as viewed from the first direction,
a width of each of the first metal wires in a third direction crossing the first and second directions at substantially right angles is larger at a center in the second direction of the first metal wire than at each end in the second direction of the first metal wire, and
a width of each of the second metal wires in the third direction is smaller at a center in the second direction of the second metal wire than at each end in the second direction of the second metal wire.

15. The device of claim 11, wherein, in plan view as viewed from the first direction,
a width of each of the first metal wires in a third direction crossing the first and second directions at substantially right angles is larger at a center in the second direction of the first metal wire than at each end in the second direction of the first metal wire, and
a width of each of the second metal wires in the third direction is smaller at a center in the second direction of the second metal wire than at each end in the second direction of the second metal wire.

16. The device of claim 1, further comprising a wire penetrating through the memory cell array to be connected to the first semiconductor layer, while being electrically isolated from the memory cell array, wherein
the wire extends in a direction crossing the first and second metal wires in plan view as viewed from the first direction.

17. The device of claim 16, wherein the wire crosses the first and second metal wires at substantially right angles in plan view as viewed from the first direction.

18. The device of claim 16, wherein the wire includes an insulating film provided on an inner wall of a slit that penetrate through the memory cell array and reaches the first semiconductor layer, and a conductive material embedded inside the insulating film.
